(19) United States
(12) Patent Application Publication
(10) Pub. No.: US 2026/0082945 A1
(43) Pub. Date: Mar. 19, 2026

(54) SEMICONDUCTOR DEVICE AND VEHICLE

(71) Applicant: Rohm Co., Ltd., Kyoto-shi (JP)

(72) Inventors: Yoshimasa FUJISADA, Kyoto-shi (JP); Koshun SAITO, Kyoto-shi (JP)

(21) Appl. No.: 19/394,119

(22) Filed: Nov. 19, 2025

Related U.S. Application Data
(63) Continuation of application No. PCT/JP2024/016404, filed on Apr. 26, 2024.

(30) Foreign Application Priority Data
May 26, 2023 (JP) 2023-087106

(51) Int. Cl. H01L 23/495; H01L 23/00

(52) U.S. Cl. CPC H10W 70/481; H10W 70/417; H10W 72/07652; H10W 72/627; H10W 72/646; H10W 72/647; H10W 72/6478; H10W 72/871; H10W 72/884; H10W 72/886; H10W 90/736; H10W 90/755; H10W 90/767

(57) ABSTRACT

A semiconductor device includes a first lead including a base portion, a semiconductor element mounted on one side in a thickness direction of the base portion and having a first electrode disposed on the one side in the thickness direction and a second electrode disposed on the other side in the thickness direction, a second lead spaced apart from the base portion in a first direction orthogonal to the thickness direction, a first conductive member including a first portion bonded to the first electrode and a second portion bonded to the second lead and electrically connected to the first electrode and the second lead, a first bonding layer interposed between, and bonded to the base portion and the second electrode, and a second bonding layer interposed between, and bonded to the first electrode and the first portion. The first bonding layer includes a sintered metal.

### TECHNICAL FIELD

The present disclosure relates to a semiconductor device and a vehicle on which the semiconductor device is mounted.

### BACKGROUND ART

Various configurations have been proposed for semiconductor devices including a semiconductor element. WO-2022/014387-A1 discloses an example of a conventional semiconductor device. The device disclosed therein includes a plurality of leads, a semiconductor element, and a plurality of conductive members. The conductive members include a metal clip and a wire. The metal clip is bonded to an electrode formed on an upper surface of the semiconductor element and to a lead. The wire is bonded to an electrode formed on the upper surface of the semiconductor element and to another lead. The metal clip as the conductive member enables the semiconductor device to handle a larger current. On the other hand, as the current capacity of the semiconductor device increases, heat generation from the semiconductor element increases, raising concern that the semiconductor element may become excessively hot.

### BRIEF DESCRIPTION OF THE DRAWINGS

FIG. 1 is a perspective view of a semiconductor device according to a first embodiment of the present disclosure.

FIG. 2 is a plan view of the semiconductor device according to the first embodiment of the present disclosure.

FIG. 3 is a partial plan view of the semiconductor device according to the first embodiment of the present disclosure.

FIG. 4 is a bottom view of the semiconductor device according to the first embodiment of the present disclosure.

FIG. 5 is a side view of the semiconductor device according to the first embodiment of the present disclosure.

FIG. 6 is a front view of the semiconductor device according to the first embodiment of the present disclosure.

FIG. 7 is a cross-sectional view taken along line VII-VII of FIG. 3.

FIG. 8 is a cross-sectional view taken along line VIII-VIII of FIG. 3.

FIG. 9 is a cross-sectional view taken along line IX-IX of FIG. 3.

FIG. 10 is a cross-sectional view taken along line X-X of FIG. 3.

FIG. 11 is a partially enlarged view of FIG. 8.

FIG. 12 is a partially enlarged view of FIG. 9.

FIG. 13 is a partially enlarged view of FIG. 10.

FIG. 14 is a schematic view of a vehicle including the semiconductor device according to the first embodiment of the present disclosure.

FIG. 15 is partial plan view of a semiconductor device according to a second embodiment of the present disclosure.

FIG. 16 is a partially enlarged cross-sectional view of the semiconductor device according to the second embodiment of the present disclosure, illustrating the same section as FIG. 11.

FIG. 17 is a partial plan view of a semiconductor device according to a third embodiment of the present disclosure.

FIG. 18 is a cross-sectional view taken along line XVIII-XVIII of FIG. 17.

FIG. 19 is a cross-sectional view taken along line XIX-XIX of FIG. 17.

FIG. 20 is a partial plan view of a semiconductor device according to a fourth embodiment of the present disclosure.

FIG. 21 is a cross-sectional view taken along line XXI-XXI of FIG. 20.

### DETAILED DESCRIPTION OF EMBODIMENTS

The following describes preferred embodiments of the present disclosure in detail with reference to the drawings.

In the present disclosure, the terms such as “first”, “second”, and “third” are used merely as labels and are not intended to impose ordinal requirements on the items to which these terms refer.

In the description of the present disclosure, the expression “An object A is formed in an object B”, and “An object A is formed on an object B” imply the situation where, unless otherwise specifically noted, “the object A is formed directly in or on the object B”, and “the object A is formed in or on the object B, with something else interposed between the object A and the object B”. Likewise, the expression “An object A is disposed in an object B”, and “An object A is disposed on an object B” imply the situation where, unless otherwise specifically noted, “the object A is disposed directly in or on the object B”, and “the object A is disposed in or on the object B, with something else interposed between the object A and the object B”. Further, the expression “An object A is located on an object B” implies the situation where, unless otherwise specifically noted, “the object A is located on the object B, in contact with the object B”, and “the object A is located on the object B, with something else interposed between the object A and the object B”. Still further, the expression “An object A overlaps with an object B as viewed in a certain direction” implies the situation where, unless otherwise specifically noted, “the object A overlaps with the entirety of the object B”, and “the object A overlaps with a part of the object B”. Also, the expression “A surface A faces (a first side or a second side) in a direction B” is not limited to the situation where the angle of the surface A to the direction B is 90° and includes the situation where the surface A is inclined with respect to the direction B.

### First Embodiment

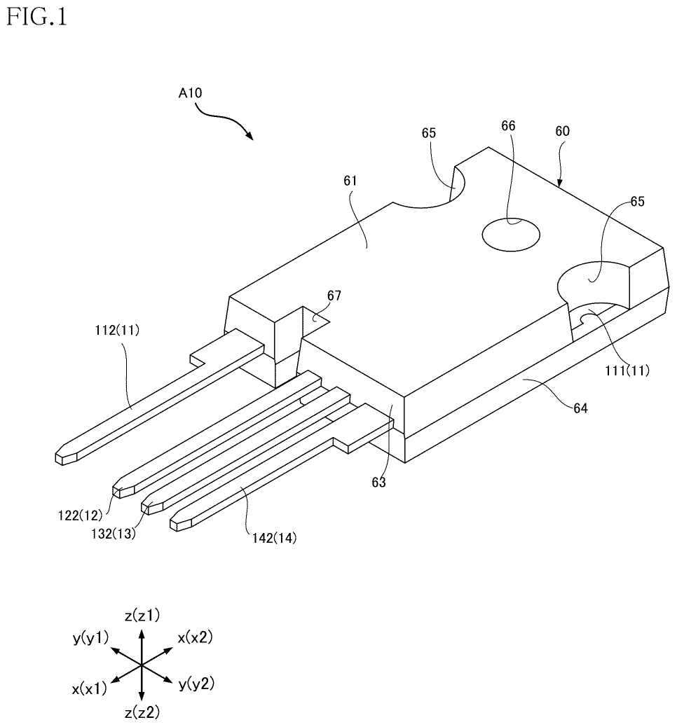

FIGS. 1 to 13 illustrate a semiconductor device according to a first embodiment of the present disclosure. The usage of a semiconductor device A10 of the present embodiment is not limited, and for example, the semiconductor device A10 may be used in electronic apparatuses and the like including a power conversion circuit such as a DC-DC converter. The semiconductor device A10 includes a first lead 11, a second lead 12, a third lead 13, a fourth lead 14, a semiconductor element 20, a first bonding layer 29, a first conductive member 30, a second bonding layer 38, a third bonding layer 39, a second conductive member 40, a third conductive member 50, and a sealing resin 60.

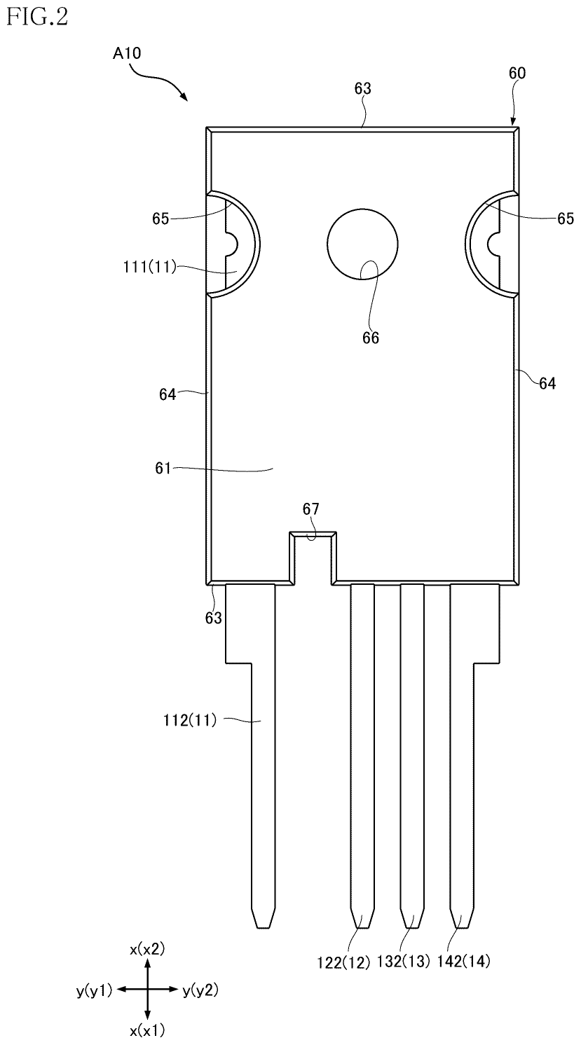

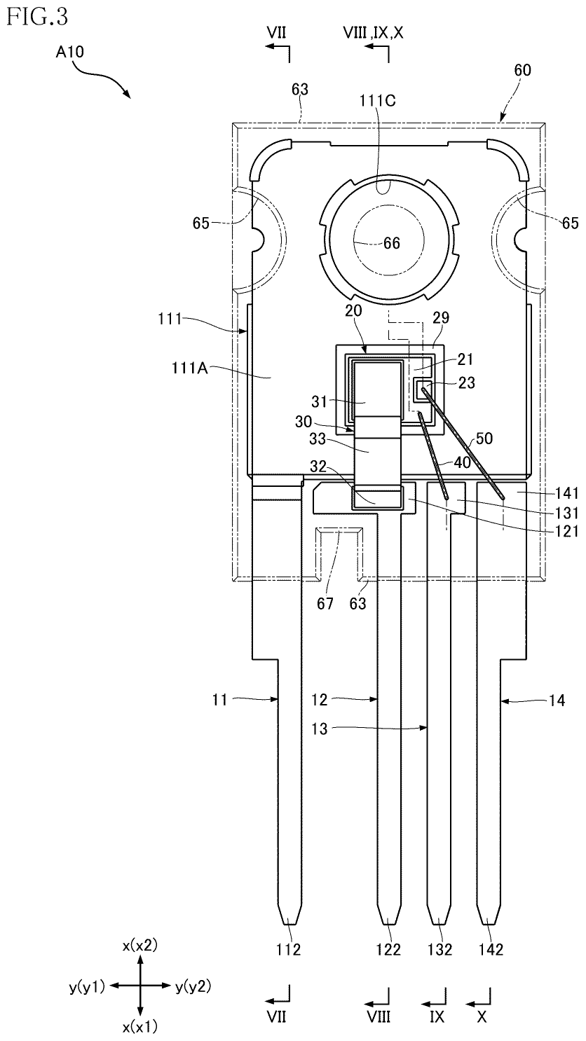

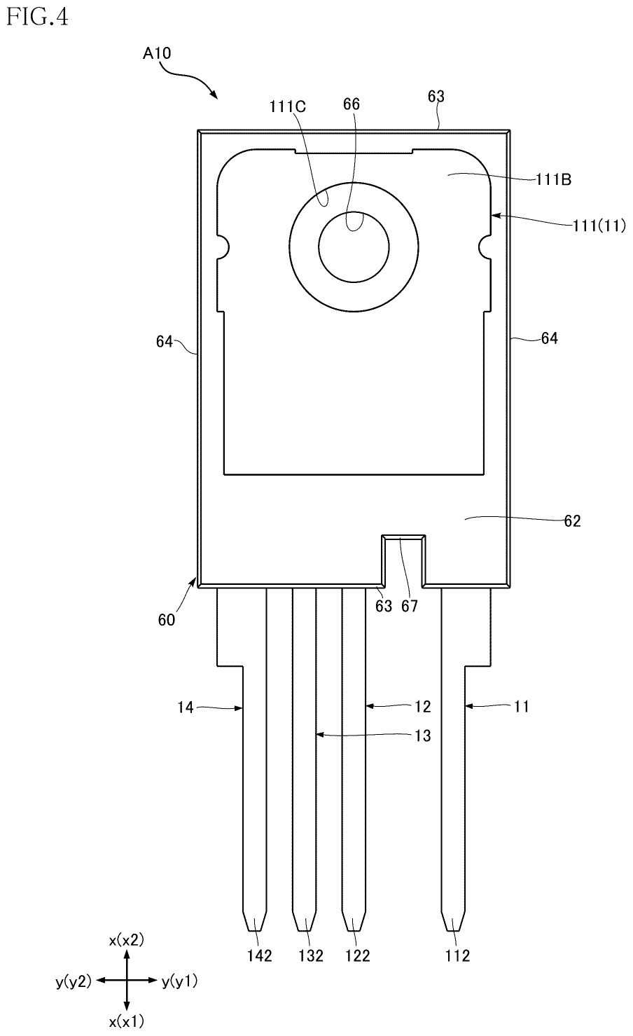

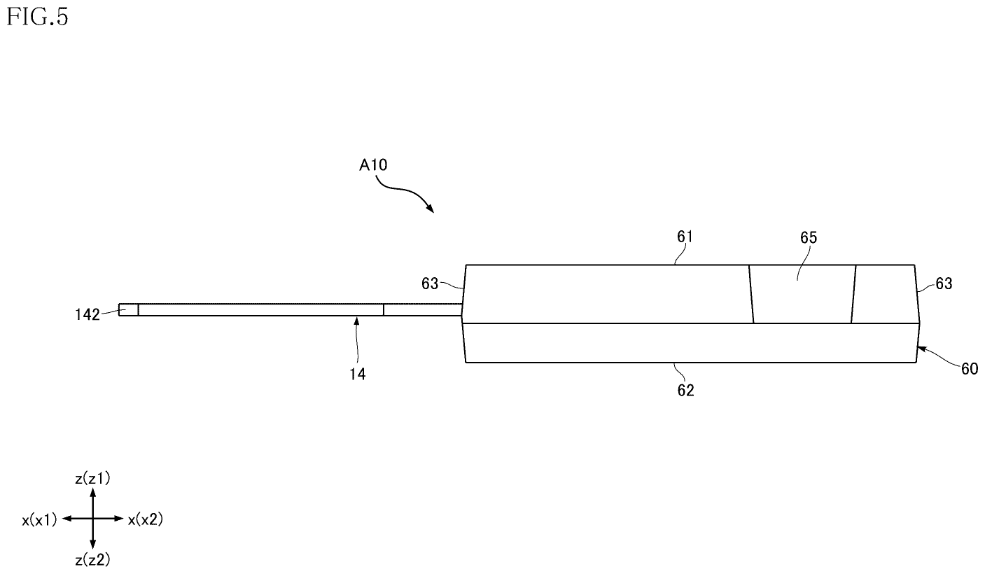

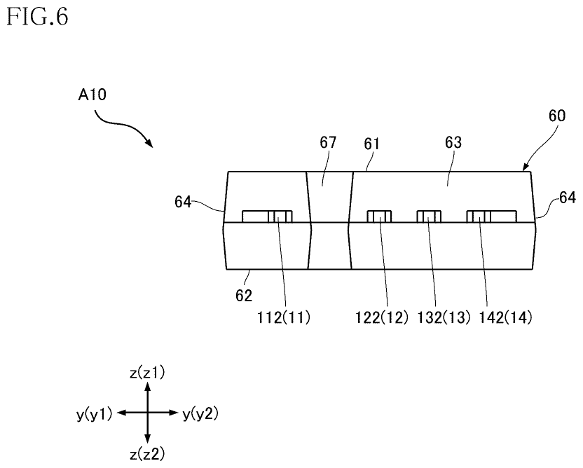

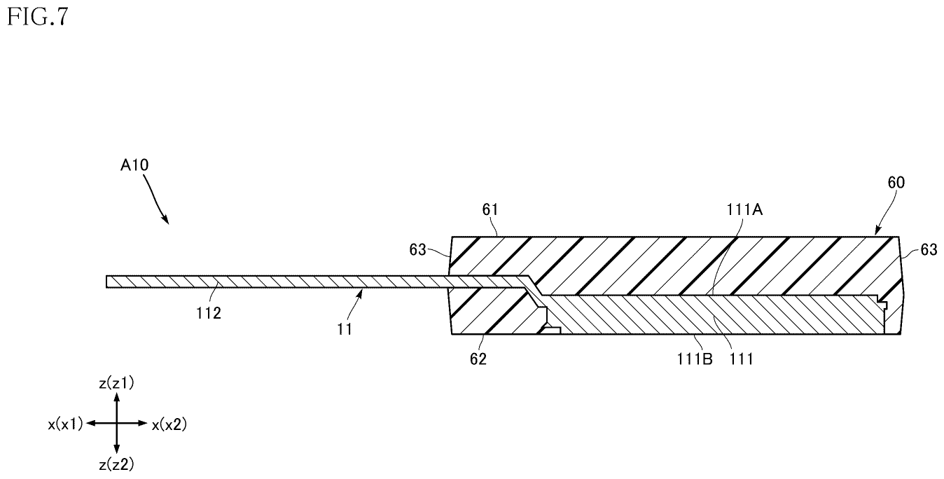

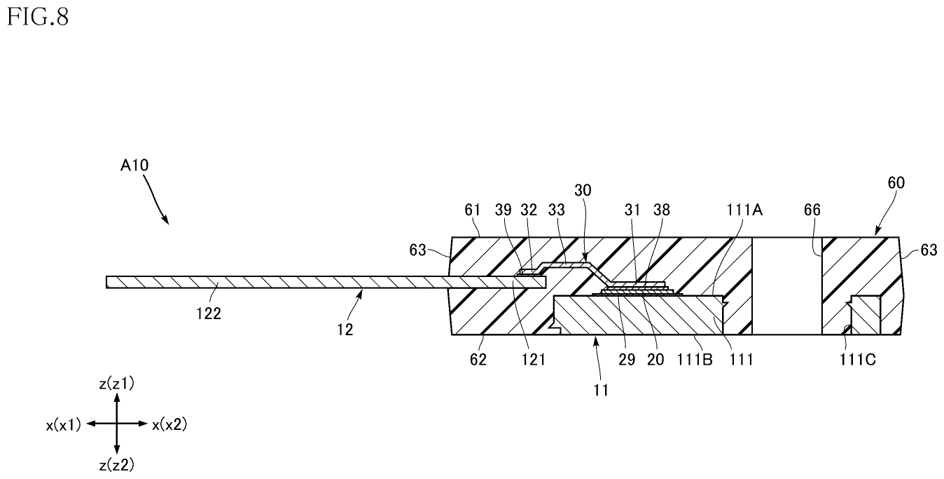

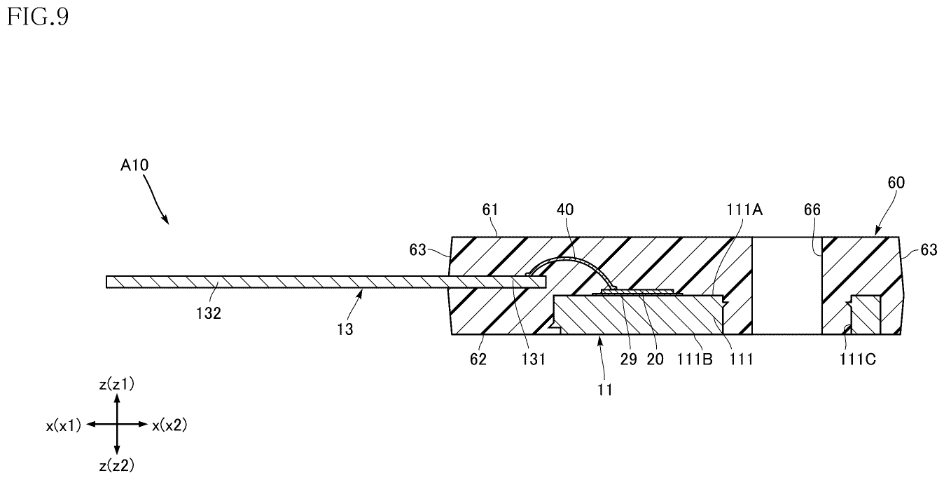

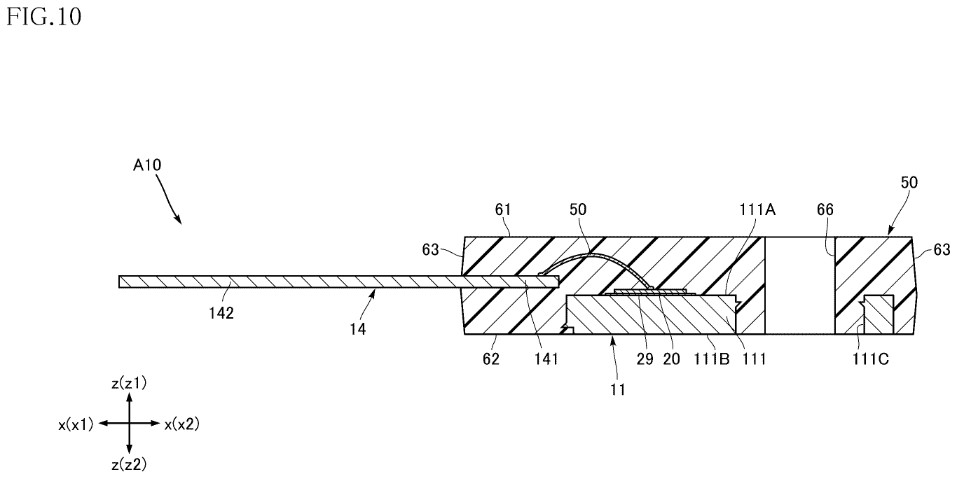

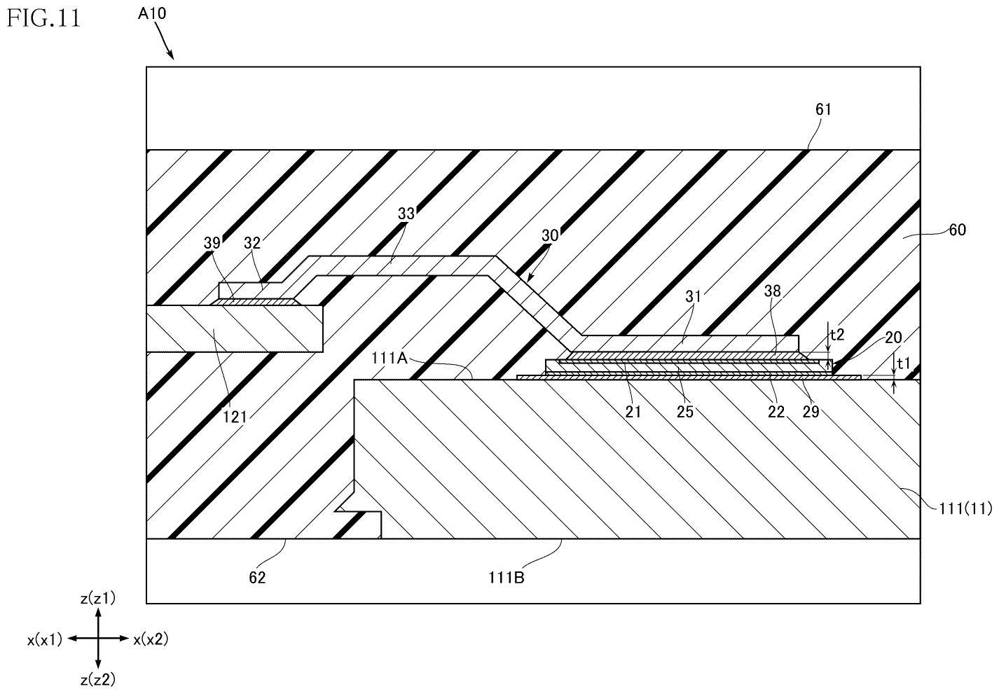

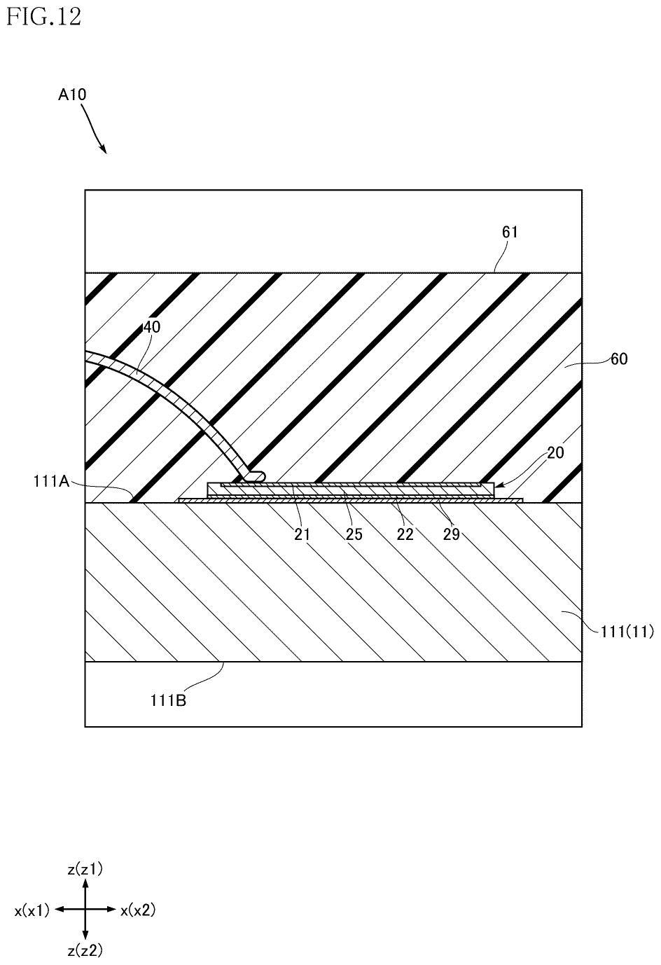

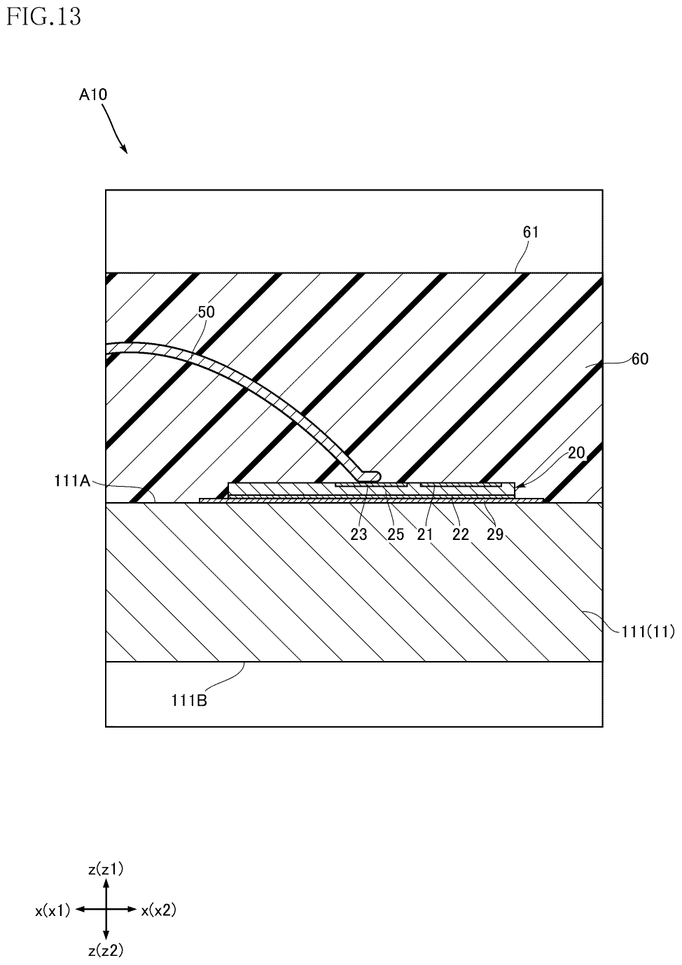

FIG. 1 is a perspective view illustrating the semiconductor device A10. FIG. 2 is a plan view illustrating the semiconductor device A10. FIG. 3 is a partial plan view illustrating the semiconductor device A10. In FIG. 3, an outline of the sealing resin 60 is represented by imaginary lines (two-dot chain lines). FIG. 4 is a bottom view illustrating the semiconductor device A10. FIG. 5 is a side view illustrating the semiconductor device A10. FIG. 6 is a front view illustrating the semiconductor device A10. FIG. 7 is a cross-sectional view taken along line VII-VII of FIG. 3. FIG. 8 is a cross-sectional view taken along line VIII-VIII of FIG. 3. FIG. 9 is a cross-sectional view taken along line IX-IX of FIG. 3. FIG. 10 is a cross-sectional view taken along line X-X of FIG. 3. FIG. 11 is a partially enlarged view of FIG. 8. FIG. 12 is a partially enlarged view of FIG. 9. FIG. 13 is a partially enlarged view of FIG. 10.

In the present disclosure, a thickness direction is referred to as a “thickness direction z”. One direction orthogonal to the thickness direction z is referred to as a “first direction x”. A direction orthogonal to the thickness direction z and the first direction x is referred to as a “second direction y”. One side in the thickness direction z is referred to as a “z1 side of the thickness direction z”, and the other side in the thickness direction z is referred to as a “z2 side of the thickness direction z”. One side in the first direction x is referred to as an “x1 side of the first direction x”, and the other side in the first direction x is referred to as an “x2 side of the first direction x”. One side in the second direction y is referred to as a “y1 side of the second direction y”, and the other side in the second direction y is referred to as a “y2 side of the second direction y”.

As shown in FIGS. 1 to 4 and 6 to 10, the first lead 11 includes a base portion 111 and a terminal portion 112. The first lead 11 is a conductive member on which the semiconductor element 20 is mounted and which forms a part of a conduction path between the semiconductor element 20 and a wiring board (not illustrated) on which the semiconductor device A10 is mounted.

The first lead 11 contains, for example, copper (Cu) or a copper alloy. The first lead 11 may have a surface metal layer (not illustrated). The surface metal layer may contain, for example, silver (Ag) or nickel (Ni).

The base portion 111 includes a first obverse surface 111A, a first reverse surface 111B, and a through hole 111C. The first obverse surface 111A faces the z1 side in the thickness direction z. The first reverse surface 111B faces the z2 side in the thickness direction z. The through hole 111C penetrates the base portion 111 in the thickness direction z. The shape of the through hole 111C is particularly not limited, and in the illustrated example, circular as viewed in the thickness direction z.

The terminal portion 112 is connected to the base portion 111 and includes a portion extending toward the x1 side in the first direction x. The base portion 111 and the terminal portion 112 are electrically connected to each other. A part of the terminal portion 112 is covered with the sealing resin 60. The part of the terminal portion 112 covered with the sealing resin 60 is bent as viewed in the second direction y. The surface of a part of the terminal portion 112 exposed from the sealing resin 60 may be plated with tin (Sn).

As shown in FIGS. 1 to 4, 6 and 8, the second lead 12 is spaced apart from the first lead 11. The second lead 12 is offset on the y2 side in the second direction y relative to the terminal portion 112 of the first lead 11. The second lead 12 is offset on the x1 side in the first direction x relative to the base portion 111 of the first lead 11. The second lead 12 is electrically connected to the semiconductor element 20 via the first conductive member 30. The second lead 12 includes a pad portion 121 and a terminal portion 122. The pad portion 121 is covered with the sealing resin 60. The pad portion 121 may be plated, for example, with silver (Ag) or tin (Sn). The terminal portion 122 is connected to the pad portion 121. The terminal portion 122 is covered with the sealing resin 60 in part, and the other part thereof is exposed from the sealing resin 60. In the first direction x, the terminal portion 122 may extend in parallel with the terminal portion 112. The surface of the terminal portion 122 may be plated with tin (Sn).

As shown in FIGS. 1 to 4, 6 and 9, the third lead 13 is spaced apart from the first lead 11 and the second lead 12. The third lead 13 is offset on the y2 side in the second direction y relative to the second lead 12. The third lead 13 is adjacent to the second lead 12 in the second direction y. The third lead 13 is offset on the x1 side in the first direction x relative to the base portion 111. The third lead 13 is electrically connected to the semiconductor element 20 via the second conductive member 40. The third lead 13 includes a pad portion 131 and a terminal portion 132. The pad portion 131 is covered with the sealing resin 60. The pad portion 131 may be plated, for example, with silver (Ag) or tin (Sn). The terminal portion 132 is connected to the pad portion 131. The terminal portion 132 is covered with the sealing resin 60 in part, and the other part thereof is exposed from the sealing resin 60. In the first direction x, the terminal portion 132 may extend in parallel with the terminal portion 112 and the terminal portion 122. The surface of the terminal portion 132 may be plated with tin (Sn).

As shown in FIGS. 1 to 4, 6 and 10, the fourth lead 14 is spaced apart from the first lead 11, the second lead 12, and the third lead 13. The fourth lead 14 is offset on the y2 side in the second direction y relative to the third lead 13. In the second direction y, the fourth lead 14 is located on the side opposite to the second lead 12 with respect to the third lead 13. The fourth lead 14 is offset on the x1 side in the first direction x relative to the base portion 111. The fourth lead 14 is electrically connected to the semiconductor element 20 via the third conductive member 50. The fourth lead 14 includes a pad portion 141 and a terminal portion 142. The pad portion 141 is covered with the sealing resin 60. The pad portion 141 may be plated, for example, with silver (Ag) or tin (Sn). The terminal portion 142 is connected to the pad portion 141. The terminal portion 142 is covered with the sealing resin 60 in part, and the other part thereof is exposed from the sealing resin 60. In the first direction x, the terminal portion 142 may extend in parallel with the terminal portion 112, the terminal portion 122, and the terminal portion 132. The surface of the terminal portion 142 may be plated with tin (Sn).

As shown in FIGS. 3 and 8 to 13, the semiconductor element 20 is mounted on the first obverse surface 111A of the base portion 111. In the semiconductor device A10, a specific configuration of the semiconductor element 20 is not particularly limited. In the present embodiment, the semiconductor element 20 is a switching element such as an n-channel type MOSFET (Metal-Oxide-Semiconductor Field-Effect Transistor) of a vertical structure. The semiconductor element 20 is not limited to a MOSFET. The semiconductor element 20 may be another transistor such as an IGBT (Insulated Gate Bipolar Transistor). Further, the semiconductor element 20 may be an LSI (Large Scale Integration) or a diode. As viewed in the thickness direction z, the semiconductor element 20 has a rectangular shape. The semiconductor element 20 is located at a central portion of the base portion 111 in the second direction y.

The semiconductor element 20 includes a semiconductor layer 25, a first electrode 21, a second electrode 22, and a third electrode 23. A thickness (dimension along the thickness direction z) of the semiconductor element 20 is not particularly limited and is in a range from, for example, about 100 to 1000 μm.

The semiconductor layer 25 includes a compound semiconductor substrate. The main material of the compound semiconductor substrate is silicon carbide (SiC). Alternatively, silicon (Si) may be used as the main material of the compound semiconductor substrate.

The first electrode 21 is provided on the semiconductor layer 25 on the z1 side in the thickness direction z. A current corresponding to power after conversion of the semiconductor element 20 flows through the first electrode 21. In the present embodiment, the first electrode 21 is a source electrode.

The second electrode 22 is provided on the semiconductor layer 25 on the z2 side in the thickness direction z. The second electrode 22 faces the first obverse surface 111A of the base portion 111 of the first lead 11. A current corresponding to power before conversion of the semiconductor element 20 flows through the second electrode 22. In the present embodiment, the second electrode 22 is a drain electrode. The second electrode 22 is conductively bonded to the first obverse surface 111A via the first bonding layer 29. The first bonding layer 29 is interposed between the first obverse surface 111A (base portion 111) and the second electrode 22, and is bonded to the base portion 111 and the second electrode 22. The first bonding layer 29 is made of a conductive material and, specifically, includes a sintered metal. The first bonding layer 29 may contain, for example, sintered silver, but is not limited thereto and may contain another sintered metal such as sintered copper. A thickness of the first bonding layer 29 (a dimension t1 along the thickness direction z) is not particularly limited and is, for example, 50 μm or less, and preferably in a range from about 20 to 30 μm.

The third electrode 23 is provided on the semiconductor layer 25 on the z1 side in the thickness direction z. The third electrode 23 is spaced apart from the first electrode 21. A voltage for driving the semiconductor element 20 is applied to the third electrode 23. In the present embodiment, the third electrode 23 is a gate electrode. As viewed in the thickness direction z, the third electrode 23 has an area smaller than an area of the first electrode 21. In the illustrated example, as viewed in the thickness direction z, the third electrode 23 is located on the y2 side in the second direction y and at a central portion of the semiconductor element 20 in the first direction x. The first electrode 21 is provided on most of the semiconductor layer 25 on the z1 side in the thickness direction z, except in a region where the third electrode 23 is provided.

The first lead 11 is electrically connected to the second electrode 22 of the semiconductor element 20. The terminal portion 112 serves as a drain terminal of the semiconductor device A10. The second lead 12 is electrically connected to the first electrode 21 of the semiconductor element 20. The terminal portion 122 serves as a source terminal of the semiconductor device A10. The third lead 13 is electrically connected to the first electrode 21 of the semiconductor element 20. The terminal portion 132 serves as a source-sense terminal of the semiconductor device A10. The fourth lead 14 is electrically connected to the third electrode 23 of the semiconductor element 20. The terminal portion 142 serves as a gate terminal of the semiconductor device A10.

As shown in FIGS. 3, 8 and 11, the first conductive member 30 is conductively bonded to the first electrode 21 of the semiconductor element 20 and to the pad portion 121 of the second lead 12. The first conductive member 30 is, for example, a plate-shaped metal member. The first conductive member 30 may contain copper (Cu), for example. The first conductive member 30 may be a plate-shaped metal member with appropriate bends. In the illustrated example, the first conductive member 30 is a pre-cut Cu clip (metal clip). The first conductive member 30 is elongated in the first direction x. A thickness (dimension along the thickness direction z) of the first conductive member 30 is not particularly limited, and is in a range from, for example, about 150 to 250 μm.

The first conductive member 30 includes a first portion 31, a second portion 32, and a first intermediate portion 33.

The first portion 31 is conductively bonded to the first electrode 21 via the second bonding layer 38. The second bonding layer 38 is interposed between the first electrode 21 and the first portion 31, and is bonded to the first electrode 21 and the first portion 31. The second bonding layer 38 is made of a conductive material, and includes a conductive paste, for example. The second bonding layer 38 may include solder, silver (Ag) paste or the like, with solder being the preferred option. A thickness (dimension t2 along the thickness direction z) of the second bonding layer 38 is not particularly limited, and is, for example, 120 μm or less, preferably in a range from about 30 to 50 μm. In the present embodiment, the first bonding layer 29 has a thickness (dimension t1 along the thickness direction z) smaller than a thickness (dimension t2 along the thickness direction z) of the second bonding layer 38. In the illustrated example, the first portion 31 is located at the end of the first conductive member 30 on the x2 side in the first direction x. As viewed in the thickness direction z, the first portion 31 has a rectangular shape.

The second portion 32 is conductively bonded to the pad portion 121 of the second lead 12 via the third bonding layer 39. The third bonding layer 39 is interposed between the pad portion 121 (second lead 12) and the second portion 32, and is bonded to the second lead 12 and the second portion 32. The third bonding layer 39 is made of a conductive material, and includes a conductive paste, for example. The third bonding layer 39 may include solder, silver (Ag) paste or the like, with solder being the preferred option. A thickness (dimension along the thickness direction z) of the third bonding layer 39 is not particularly limited and is, for example, 120 μm or less, preferably in a range from about 30 to 50 μm. In the illustrated example, the second portion 32 is located at the end of the first conductive member 30 on the x1 side in the first direction x. As viewed in the thickness direction z, the second portion 32 has a rectangular shape.

As viewed in the thickness direction z, the first intermediate portion 33 is located between the first portion 31 and the second portion 32. The first intermediate portion 33 is connected to the first portion 31 and the second portion 32. As viewed in the thickness direction z, the first intermediate portion 33 has a rectangular shape. The connected portion of the first intermediate portion 33 to the first portion 31 and the second portion 32 is bent as viewed in the second direction y. The portion of the first intermediate portion 33 other than the bent portions extend along the x-y plane and are offset on the z1 side in the thickness direction z relative to the first portion 31 and the second portion 32.

As shown in FIGS. 3, 9 and 12, the second conductive member 40 is conductively bonded to the first electrode 21 of the semiconductor element 20 and to the pad portion 131 of the third lead 13. In the present embodiment, the second conductive member 40 is a bonding wire. A specific configuration of the second conductive member 40 is not particularly limited, and includes cross-sectional shapes such as circular, elliptical, flattened rectangular shapes and the like. In the illustrated example, the second conductive member 40 has a circular cross-section. The second conductive member 40 may be bonded by wedge bonding, for example. A material of the second conductive member 40 is not particularly limited and includes copper (Cu) or aluminum (Al), for example.

As shown in FIGS. 3, 10 and 13, the third conductive member 50 is conductively bonded to the third electrode 23 of the semiconductor element 20 and to the pad portion 141 of the fourth lead 14. In the present embodiment, the third conductive member 50 is a bonding wire. A specific configuration of the third conductive member 50 is not particularly limited, and includes cross-sectional shapes such as circular, elliptical, flattened rectangular shapes and the like. In the illustrated example, the third conductive member 50 has a circular cross-section. The third conductive member 50 may be bonded by wedge bonding, for example. A material of the third conductive member 50 is not particularly limited and includes copper (Cu) or aluminum (Al), for example.

The semiconductor element 20 is bonded to the base portion 111 via the first bonding layer 29 by performing a sintering process on a metal material. A method for forming the first bonding layer 29 is not particularly limited, and one example is as follows. First, a paste-like metal material for sintering (e.g., silver for sintering) is applied by a dispenser onto the base portion 111 (first obverse surface 111A). Because of its low viscosity, the metal material for sintering spreads thinly over the first obverse surface 111A. Next, the metal material for sintering is subjected to a drying process, and the semiconductor element 20 is placed on the metal material for sintering. Thereafter the metal material for sintering is heat-treated, so that the first bonding layer 29 (sintered metal) is formed. During the heating process, the metal material for sintering may be pressurized.

The first conductive member 30 is bonded to the first electrode 21 and the second lead 12 (pad portion 121) via the second bonding layer 38 and the third bonding layer 39 by a reflow process, for example. A method for forming the second bonding layer 38 and the third bonding layer 39 is not particularly limited, and one example is as follows. First, conductive paste materials are applied onto the first electrode 21 and the pad portion 121, respectively. Here, the conductive paste material exhibits higher viscosity than the metal material for sintering, and spreads less than the metal material for sintering. Next, the first conductive member 30 is disposed on the conductive paste material and heated in a reflow furnace. As a result, the second bonding layer 38 and the third bonding layer 39 are formed. After bonding the first conductive member 30, the second conductive member 40 and the third conductive member 50 are bonded.

The first bonding layer 29 is made of a sintered metal and exhibits high thermal conductivity. More specifically, the first bonding layer 29 has higher thermal conductivity than the second bonding layer 38 made of a conductive paste.

As shown in FIGS. 1 to 10, the sealing resin 60 covers the semiconductor element 20, the first conductive member 30, the second conductive member 40, the third conductive member 50, a part of each of the first lead 11, the second lead 12, the third lead 13 and the fourth lead 14. The sealing resin 60 has electrical insulating properties. The sealing resin 60 is made of a material including, for example, a black epoxy resin. The sealing resin 60 includes a resin obverse surface 61, a resin reverse surface 62, a pair of first resin side surfaces 63, a pair of second resin side surfaces 64, a pair of openings 65, a mounting hole 66, and a recess 67.

The resin obverse surface 61 faces the z1 side in the thickness direction z. The resin reverse surface 62 faces the z2 side in the thickness direction z. From the resin reverse surface 62, the first reverse surface 111B of the base portion 111 is exposed. The first reverse surface 111B and the resin reverse surface 62 are flush with each other.

The pair of first resin side surfaces 63 are spaced apart from each other in the first direction x. Each first resin side surface 63 is connected to the resin obverse surface 61 and the resin reverse surface 62. From the first resin side surface 63 facing the x1 side in the first direction x, the terminal portion 112 of the first lead 11, the terminal portion 122 of the second lead 12, the terminal portion 132 of the third lead 13, and the terminal portion 142 of the fourth lead 14 project.

The pair of second resin side surfaces 64 are spaced apart from each other in the second direction y. Each second resin side surface 64 is connected to the resin obverse surface 61 and the resin reverse surface 62.

The pair of openings 65 are spaced apart from each other in the second direction y. Each of the openings 65 is recessed inward of the sealing resin 60 from the resin obverse surface 61 and a corresponding one of the pair of second resin side surfaces 64. Through the pair of openings 65, a part of the first obverse surface 111A of the base portion 111 of the first lead 11 is exposed.

The mounting hole 66 penetrates the sealing resin 60 from the resin obverse surface 61 to the resin reverse surface 62 in the thickness direction z. As viewed in the thickness direction z, the mounting hole 66 is encompassed within the through hole 111C of the base portion 111 of the first lead 11. An inner circumferential surface of the base portion 111 defining the through hole 111C is covered with the sealing resin 60. In other words, as viewed in the thickness direction z, the mounting hole 66 has a maximum dimension smaller than a dimension of the through hole 111C.

The recess 67 is located between the terminal portion 112 and the terminal portion 122 in the second direction y. The recess 67 is recessed from the first resin side surface 63 on the x1 side in the first direction x toward the x2 side in the first direction x.

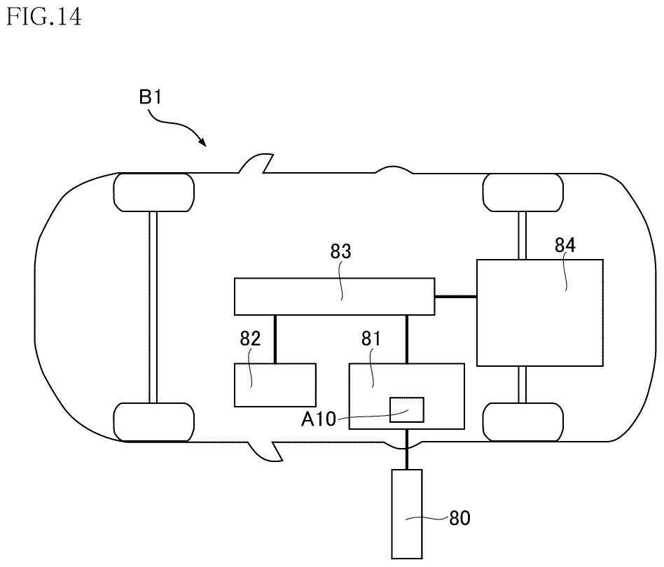

Next, with reference to FIG. 14, an example of use of the semiconductor device A10 is described. FIG. 14 is a schematic view of a vehicle B1 on which the semiconductor device A10 is mounted. The vehicle B1 is, for example, an electric vehicle (EV).

As shown in FIG. 14, the vehicle B1 includes an AC-DC converter 81, a power reception device 82, a storage battery 83, and a drive system 84. The semiconductor device A10 configures part of the AC-DC converter 81. When the vehicle B1 is supplied with AC power from a charging facility 80 serving as an AC power source installed outdoors or the like, the AC-DC converter 81 converts the AC power into high-voltage DC power. The AC-DC converter 81 supplies the high-voltage DC power to the storage battery 83. The power reception device 82 supplies power to the storage battery 83 through a wireless charging system. In one example, the power reception device 82 receives power by electromagnetic induction from a wireless charger (not illustrated) installed in a parking area or the like. Power stored in the storage battery 83 is supplied to the drive system 84 including an inverter, an AC motor, and a transmission. The drive system 84 drives the vehicle B1. The AC-DC converter 81 is an example of the “power converter” of the present disclosure.

Next, operative effects of the semiconductor device A10 are as follows.

The semiconductor device A10 includes the first lead 11, the second lead 12, the semiconductor element 20, the first conductive member 30, the first bonding layer 29, and the second bonding layer 38. The first conductive member 30 is conductively bonded to the first electrode 21 of the semiconductor element 20 and to the second lead 12. The first bonding layer 29 is interposed between the base portion 111 of the first lead 11 and the second electrode 22 of the semiconductor element 20, and is bonded to the base portion 111 and the second electrode 22. The second bonding layer 38 is interposed between the first electrode 21 and the first portion 31 of the first conductive member 30, and is bonded to the first electrode 21 and the first portion 31. The first bonding layer 29 includes a sintered metal. Such a configuration enables the semiconductor device A10 to handle a large current through the first conductive member 30. In addition, the first bonding layer 29 interposed between the base portion 111 and the second electrode 22 includes a sintered metal, and hence exhibits high thermal conductivity. Accordingly, even when heat generation from the semiconductor element 20 rises with an increase in current capacity of the semiconductor device A10, heat generated from the semiconductor element 20 can be efficiently conducted to the base portion 111 (first lead 11) via the first bonding layer 29. Therefore, the semiconductor device A10 is advantageous for improving heat dissipation while achieving a high current capacity.

The second bonding layer 38 includes a conductive paste that is interposed between the first electrode 21 of the semiconductor element 20 and the first portion 31 of the first conductive member 30. A conductive paste material for forming the second bonding layer 38 has high viscosity and hardly spreads when applied. This may increase the size of the first portion 31 bonded to the first electrode 21 via the second bonding layer 38, without the second bonding layer 38 sagging along a side surface of the semiconductor element 20. Accordingly, the semiconductor device A10 is suitable for handling a larger current and can achieve improved heat dissipation and reliability.

The first bonding layer 29 has a thickness (dimension t1 along the thickness direction z) smaller than a thickness (dimension t2 along the thickness direction z) of the second bonding layer 38. Accordingly, heat generated from the semiconductor element 20 can be more efficiently conducted to the base portion 111 (first lead 11) via the first bonding layer 29. This is more preferable for improving heat dissipation of the semiconductor device A10.

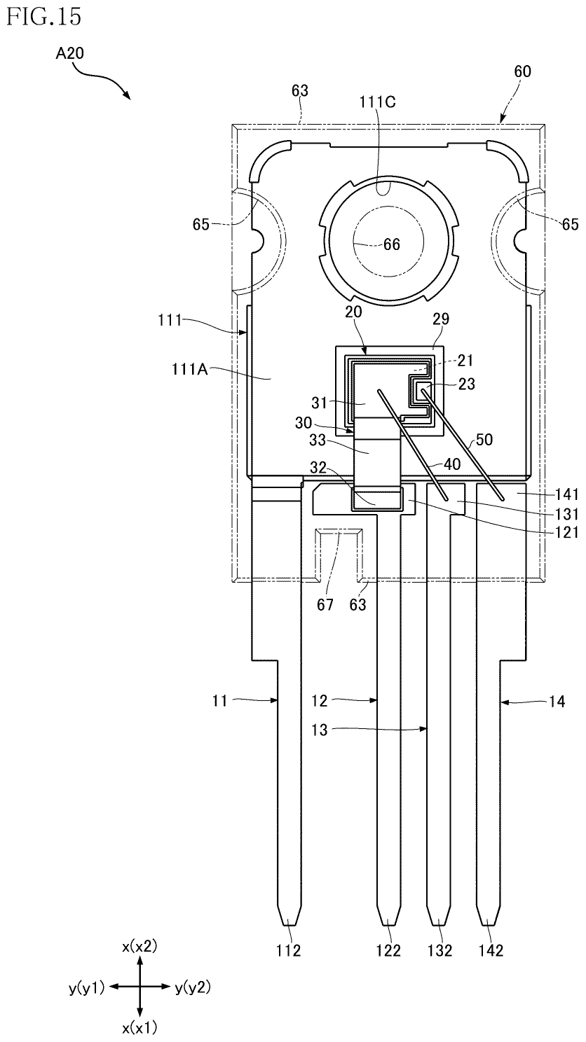

FIGS. 15 to 21 illustrate other embodiments of the present disclosure. In these figures, elements identical or similar to those of the embodiment described above are marked with the same numerals, and redundant descriptions are omitted. Various parts of embodiments may be selectively used in any appropriate combination as long as they are technically compatible.

### Second Embodiment

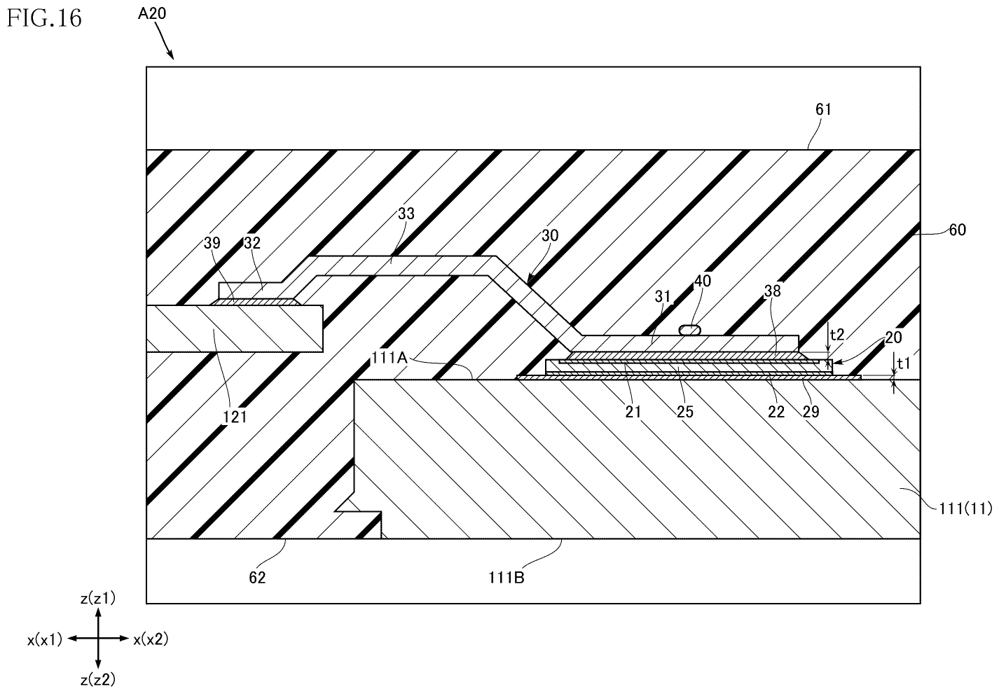

FIGS. 15 and 16 illustrate a semiconductor device according to a second embodiment of the present disclosure. FIG. 15 is a partial plan view of a semiconductor device A20 according to the present embodiment. FIG. 16 is a partially enlarged cross-sectional view of the semiconductor device A20, illustrating the same section as FIG. 11. In FIG. 15, an outline of the sealing resin 60 is represented by imaginary lines (two-dot chain lines). The semiconductor device A20 of the present embodiment differs from the semiconductor device A10 in the configuration of the first conductive member 30 and the arrangement of the second conductive member 40.

In the present embodiment, the second conductive member 40 is conductively bonded to the first portion 31 of the first conductive member 30 and to the pad portion 131 of the third lead 13. The second conductive member 40 is electrically connected to the first electrode 21 of the semiconductor element 20 via the first conductive member 30 (first portion 31).

In the present embodiment, the first portion 31 is U-shaped as viewed in the thickness direction z. The first portion 31 includes portions provided on both sides of the third electrode 23 in the first direction x, and overlaps with a majority of the first electrode 21 as viewed in the thickness direction z.

In the semiconductor device A20, the first bonding layer 29 is interposed between the base portion 111 of the first lead 11 and the second electrode 22 of the semiconductor element 20, and is bonded to the base portion 111 and the second electrode 22. The second bonding layer 38 is interposed between the first electrode 21 and the first portion 31 of the first conductive member 30, and is bonded to the first electrode 21 and the first portion 31. The first bonding layer 29 includes a sintered metal. Such a configuration enables the semiconductor device A20 to handle a large current through the first conductive member 30. In addition, the first bonding layer 29 interposed between the base portion 111 and the second electrode 22 includes a sintered metal, and hence exhibits high thermal conductivity. Accordingly, even when heat generation from the semiconductor element 20 increases with an increase in current capacity of the semiconductor device A20, heat generated from the semiconductor element 20 can be efficiently conducted to the base portion 111 (first lead 11) via the first bonding layer 29. Therefore, the semiconductor device A20 is advantageous for improving heat dissipation while achieving a high current capacity. In addition, the semiconductor device A20 may have a configuration in common with the semiconductor device A10, thereby achieving the same effect as the semiconductor device A10.

In the semiconductor device A20, the second conductive member 40 is conductively bonded to the first portion 31 (first conductive member 30) and to the third lead 13. The second conductive member 40 is electrically connected to the first electrode 21 via the first conductive member 30. In the present embodiment, it is unnecessary to provide space on the first electrode 21 for bonding the second conductive member 40 with a bonding tool. Accordingly, the area of the first portion 31 as viewed in the thickness direction z can be increased, thereby permitting an increase in the size of the first conductive member 30. Thus, the semiconductor device A20 is suitable for handling a larger current.

### Third Embodiment

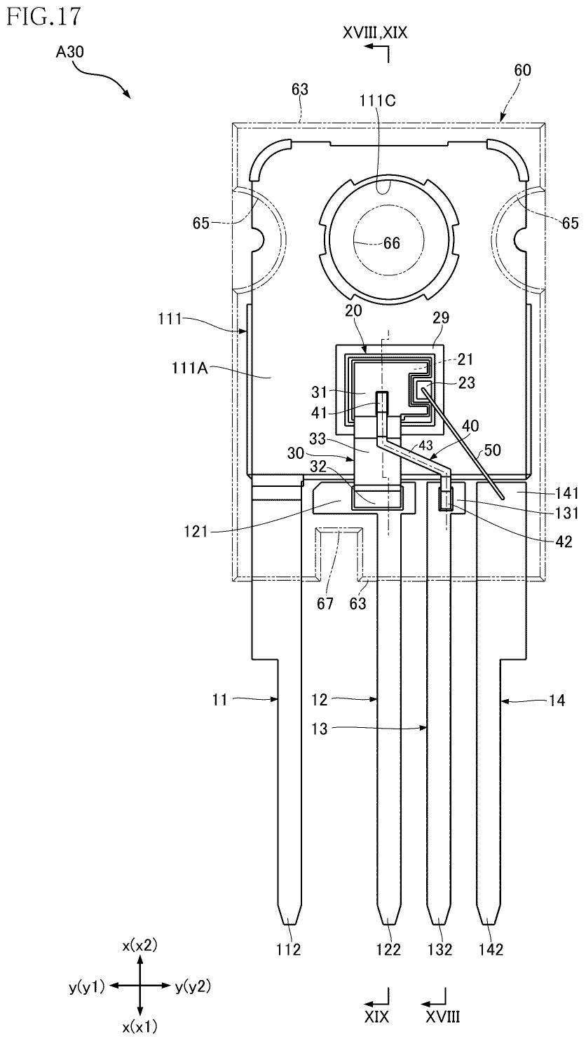

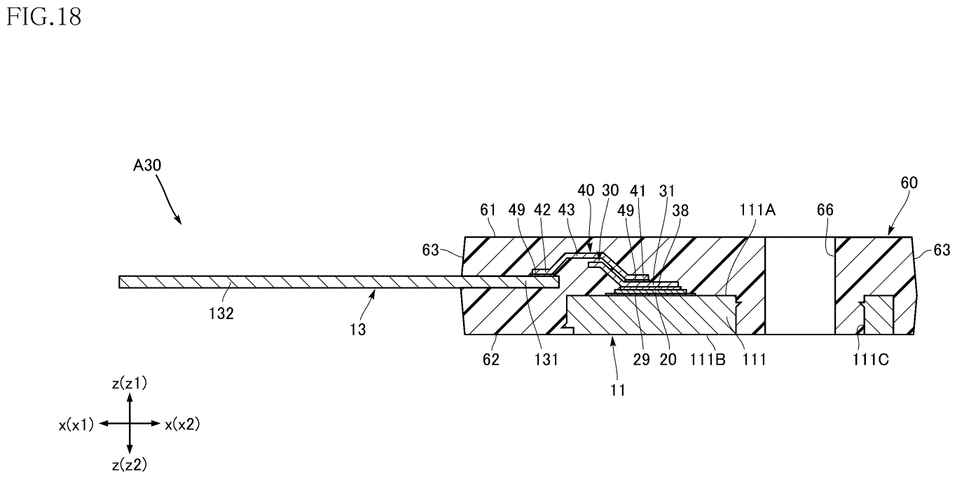

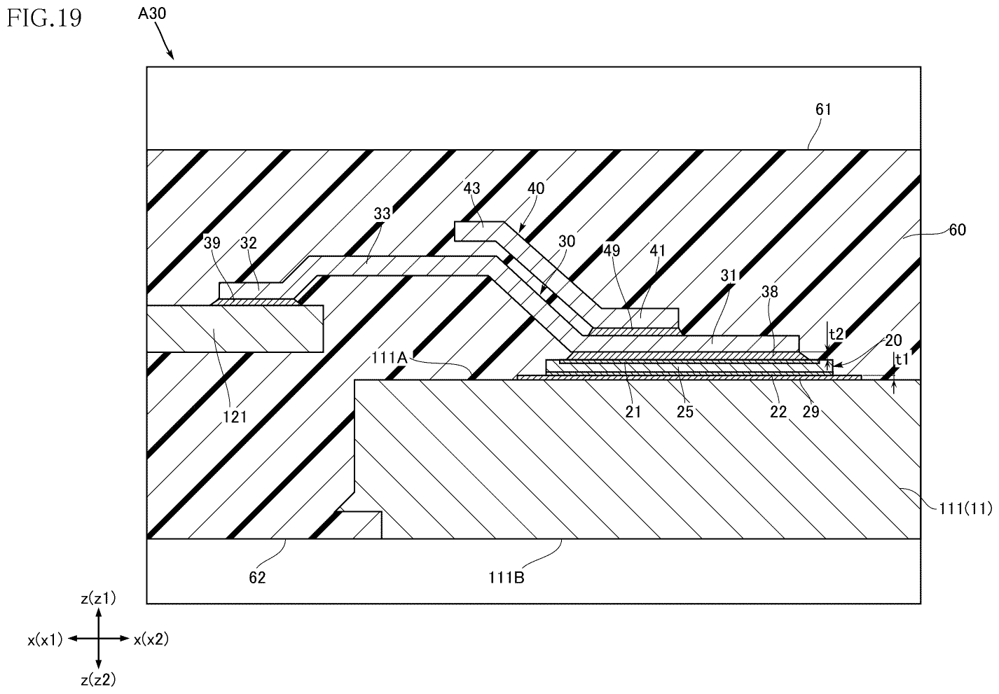

FIGS. 17 to 19 illustrate a semiconductor device according to a third embodiment of the present disclosure. FIG. 17 is a partial plan view of a semiconductor device A30. FIG. 18 is a cross-sectional view taken along line XVIII-XVIII of FIG. 17. FIG. 19 is a cross-sectional view taken along line XIX-XIX of FIG. 17. In FIG. 17, an outline of the sealing resin 60 is represented by imaginary lines (two-dot chain lines). The semiconductor device A30 of the present embodiment differs from the semiconductor device A10 in the configurations of the first conductive member 30 and the second conductive member 40.

In the present embodiment, the second conductive member 40 is conductively bonded to the first portion 31 of the first conductive member 30 and to the pad portion 131 of the third lead 13. The second conductive member 40 is, for example, a plate-shaped metal member. The second conductive member 40 may contain copper (Cu), for example. The second conductive member 40 may be a plate-shaped metal member with appropriate bends. In the present embodiment, the second conductive member 40 includes a third portion 41, a fourth portion 42, and a second intermediate portion 43.

The third portion 41 is bonded to the first portion 31 of the first conductive member 30 via a bonding layer 49. The bonding layer 49 is made of a conductive material, and includes solder, silver (Ag) paste or the like, for example. The third portion 41 is electrically connected to the first electrode 21 of the semiconductor element 20 via the first conductive member 30 (first portion 31). In the illustrated example, the third portion 41 is located at the end of the second conductive member 40 on the x2 side in the first direction x.

The fourth portion 42 is bonded to the pad portion 131 of the third lead 13 via the bonding layer 49. The bonding layer 49 is made of a conductive material, and includes solder, silver (Ag) paste or the like, for example. In the illustrated example, the fourth portion 42 is located at the end of the second conductive member 40 on the x1 side in the first direction x.

As viewed in the thickness direction z, the second intermediate portion 43 is located between the third portion 41 and the fourth portion 42. The second intermediate portion 43 is connected to the third portion 41 and the fourth portion 42. The connected portion of the second intermediate portion 43 to the third portion 41 or the fourth portion 42 is bent as viewed in the second direction y. The portion of the second intermediate portion 43 other than the bent portions extend along the x-y plane and are offset on the z1 side relative to the third portion 41 and the fourth portion 42. The portion of the second intermediate portion 43 other than the bent portions is progressively offset toward the y2 side in the second direction y as it extends toward the x1 side in the first direction x, and extends in a direction crossing the first direction x and the second direction y.

In the present embodiment, the first portion 31 is U-shaped as viewed in the thickness direction z. The first portion 31 includes portions provided on both sides of the third electrode 23 in the first direction x, and overlaps with a majority of the first electrode 21, as viewed in the thickness direction z.

In the semiconductor device A30, the first bonding layer 29 is interposed between the base portion 111 of the first lead 11 and the second electrode 22 of the semiconductor element 20, and is bonded to the base portion 111 and the second electrode 22. The second bonding layer 38 is interposed between the first electrode 21 and the first portion 31 of the first conductive member 30, and is bonded to the first electrode 21 and the first portion 31. The first bonding layer 29 includes a sintered metal. Such a configuration enables the semiconductor device A30 to handle a large current through the first conductive member 30. In addition, the first bonding layer 29 interposed between the base portion 111 and the second electrode 22 includes a sintered metal, and hence exhibits high thermal conductivity. Accordingly, even when heat generation from the semiconductor element 20 increases with an increase in current capacity of the semiconductor device A30, heat generated from the semiconductor element 20 can be efficiently conducted to the base portion 111 (first lead 11) via the first bonding layer 29. Therefore, the semiconductor device A30 is advantageous for improving heat dissipation while achieving a high current capacity. In addition, the semiconductor device A30 may have a configuration in common with the semiconductor device A10, thereby achieving the same effect as the semiconductor device A10.

In the semiconductor device A30, the second conductive member 40 is conductively bonded to the first portion 31 (first conductive member 30) and to the third lead 13. The second conductive member 40 is electrically connected to the first electrode 21 via the first conductive member 30. In the present embodiment, it is unnecessary to provide space on the first electrode 21 for bonding the second conductive member 40 with a bonding tool. Accordingly, the area of the first portion 31 as viewed in the thickness direction z can be increased, thereby permitting an increase in the size of the first conductive member 30. Thus, the semiconductor device A30 is suitable for handling a larger current.

### Fourth Embodiment

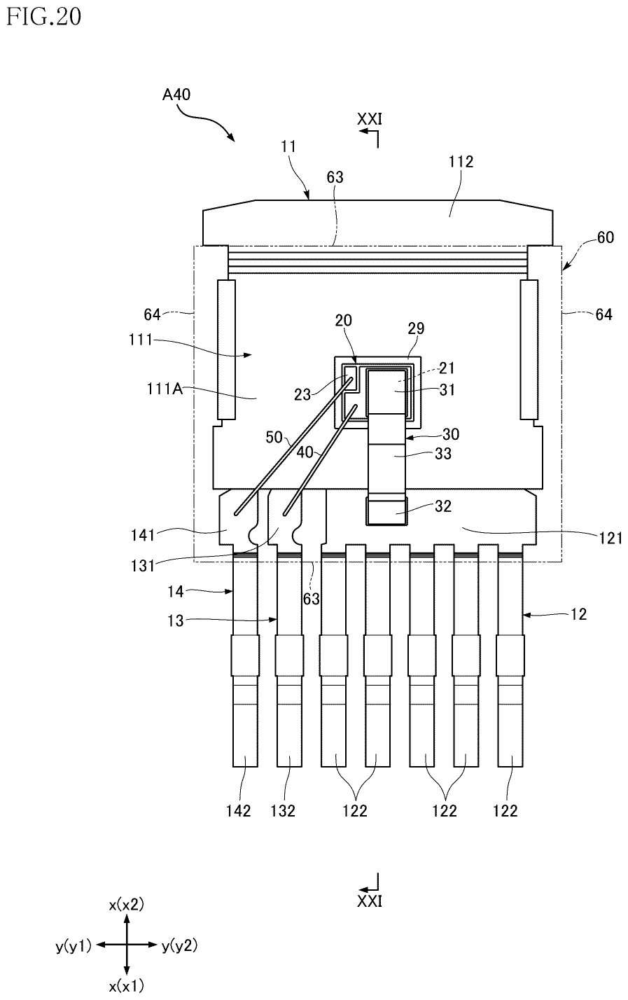

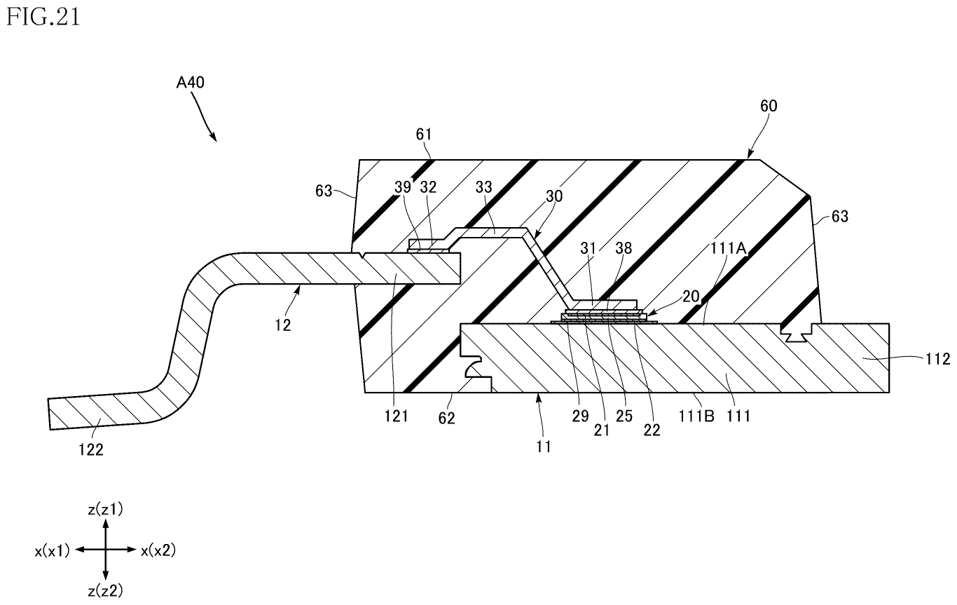

FIGS. 20 and 21 illustrate a semiconductor device according to a fourth embodiment of the present disclosure. FIG. 20 is a partial plan view of a semiconductor device A40 according to the present embodiment. FIG. 21 is a cross-sectional view taken along line XXI-XXI of FIG. 20. In FIG. 20, an outline of the sealing resin 60 is represented by imaginary lines (two-dot chain lines). The semiconductor device A40 differs from the semiconductor device A10 in the configurations of the first lead 11, the second lead 12, the third lead 13 and the fourth lead 14, and other elements are adjusted accordingly.

In the first lead 11, the terminal portion 112 is connected to the base portion 111, and is located on the x2 side in the first direction x with respect to the base portion 111. The terminal portion 112 is elongated in the second direction y. As shown in FIG. 21, the terminal portion 112 is electrically connected to the second electrode 22 (drain electrode) of the semiconductor element 20 via the base portion 111 and the first bonding layer 29. The terminal portion 112 serves as a drain terminal for the first conductive member 30.

The first bonding layer 29 is interposed between the base portion 111 and the second electrode 22, and is bonded to the base portion 111 and the second electrode 22. The first bonding layer 29 is made of a conductive material and, specifically, includes a sintered metal. The first bonding layer 29 may contain, for example, sintered silver, but is not limited thereto and may contain another sintered metal such as sintered copper. A thickness (dimension along the thickness direction z) of the first bonding layer 29 is not particularly limited and is, for example, 50 μm or less, and preferably in a range from about 20 to 30 μm.

As shown in FIGS. 20 and 21, the second lead 12 is spaced apart from the first lead 11, and is offset on the x1 side in the first direction x relative to the base portion 111 of the first lead 11. The second lead 12 is electrically connected to the semiconductor element 20 via a first conductive member 30. The second lead 12 includes a pad portion 121 and a plurality of (five in the illustrated example) terminal portions 122. The pad portion 121 is elongated in the second direction y, and extends from a central portion in the second direction y toward the y2 side in the second direction y as viewed in the thickness direction z. The terminal portions 122 are arranged at intervals from one another in the second direction y, and are connected to the pad portion 121. Each of the terminal portions 122 has a portion exposed from the sealing resin 60, which has an appropriate bend as viewed in the second direction y. The pad portion 121 (second lead 12) is electrically connected to the first electrode 21 (source electrode) of the semiconductor element 20 via the first conductive member 30. The terminal portions 122 serve as source terminals of the semiconductor device A40.

The third lead 13 is spaced apart from the first lead 11 and the second lead 12. The third lead 13 is offset on the y1 side in the second direction y relative to the second lead 12. The third lead 13 is adjacent to the second lead 12 in the second direction y. The third lead 13 is offset on the x1 side in the first direction x relative to the base portion 111. The third lead 13 is electrically connected to the first electrode 21 (source electrode) of the semiconductor element 20 via the second conductive member 40. The terminal portion 132 serves as a source-sense terminal of the semiconductor device A40.

The fourth lead 14 is spaced apart from the first lead 11, the second lead 12, and the third lead 13. The fourth lead 14 is offset on the y1 side in the second direction y relative to the third lead 13. The fourth lead 14 is located on the side opposite to the second lead 12 with respect to the third lead 13 in the second direction y. The fourth lead 14 is offset on the x1 side in the first direction x relative to the base portion 111. The fourth lead 14 is electrically connected to the third electrode 23 (gate electrode) of the semiconductor element 20 via the third conductive member 50. The terminal portion 142 serves as a gate terminal of the semiconductor device A40.

The first conductive member 30 is conductively bonded to the first electrode 21 of the semiconductor element 20 and to the pad portion 121 of the second lead 12. The first conductive member 30 is, for example, a plate-shaped metal member. The first conductive member 30 may contain copper (Cu). The first conductive member 30 is a plate-shaped metal member with appropriate bends. In the illustrated example, the first conductive member 30 is a pre-cut Cu clip (metal clip). The first conductive member 30 is elongated in the first direction x.

The first conductive member 30 includes the first portion 31, the second portion 32, and the first intermediate portion 33. The first portion 31 is conductively bonded to the first electrode 21 via the second bonding layer 38. The second bonding layer 38 is interposed between the first electrode 21 and the first portion 31, and is bonded to the first electrode 21 and the first portion 31. The second bonding layer 38 is made of a conductive material, and includes a conductive paste, for example. The second bonding layer 38 may include solder, silver (Ag) paste or the like, with solder being the preferred option. A thickness of the second bonding layer 38 (a dimension along the thickness direction z) is not particularly limited, and is, for example, 120 μm or less, preferably in a range from about 30 to 50 μm. In the present embodiment, the first bonding layer 29 has a thickness (dimension along the thickness direction z) smaller than a thickness (dimension along the thickness direction z) of the second bonding layer 38. In the illustrated example, the first portion 31 is located at the end of the first conductive member 30 on x2 side in the first direction x.

The second portion 32 is conductively bonded to the pad portion 121 of the second lead 12 via the third bonding layer 39. The third bonding layer 39 is interposed between the pad portion 121 (second lead 12) and the second portion 32, and is bonded to the second lead 12 and the second portion 32. The third bonding layer 39 is made of a conductive material, and includes a conductive paste, for example. The third bonding layer 39 may include solder, silver (Ag) paste or the like, with solder being the preferred option. A thickness (dimension along the thickness direction z) of the third bonding layer 39 is not particularly limited and is, for example, 120 μm or less, preferably in a range from about 30 to 50 μm. In the illustrated example, the second portion 32 is located at the end of the first conductive member 30 on the x1 side in the first direction x.

As viewed in the thickness direction z, the first intermediate portion 33 is located between the first portion 31 and the second portion 32. The first intermediate portion 33 is connected to the first portion 31 and the second portion 32. The connected portion of the first intermediate portion 33 to the first portion 31 or the second portion 32 is bent as viewed in the second direction y. The portion of the first intermediate portion 33 other than the bent portions extend along the x-y plane, and are offset on the z1 side in the thickness direction z relative to the first portion 31 and the second portion 32.

The second conductive member 40 is conductively bonded to the first electrode 21 (source electrode) of the semiconductor element 20 and to the pad portion 131 of the third lead 13. In the present embodiment, the second conductive member 40 is a bonding wire. A specific configuration of the second conductive member 40 is not particularly limited, and includes cross-sectional shapes such as circular, elliptical, flattened rectangular shapes and the like. A material of the second conductive member 40 is not particularly limited and includes copper (Cu) or aluminum (Al), for example.

The third conductive member 50 is conductively bonded to the third electrode 23 (gate electrode) of the semiconductor element 20 and to the pad portion 141 of the fourth lead 14. In the present embodiment, the third conductive member 50 is a bonding wire. A specific configuration of the third conductive member 50 is not particularly limited, and includes cross-sectional shapes such as circular, elliptical, flattened rectangular shapes and the like. A material of the third conductive member 50 is not particularly limited and includes copper (Cu) or aluminum (Al), for example. In the present embodiment, as viewed in the thickness direction z, the third electrode 23 is located near a corner of the semiconductor element 20 on the x2 side in the first direction x and the y1 side in the second direction y.

The semiconductor element 20 is bonded to the base portion 111 via the first bonding layer 29 by performing a sintering process on a metal material. A method for forming the first bonding layer 29 is not particularly limited, and one example is as follows. First, a paste-like metal material for sintering (e.g., silver for sintering) is applied by a dispenser onto the base portion 111 (first obverse surface 111A). The metal material for sintering has good fluidity and spreads thinly over the first obverse surface 111A. Next, the metal material for sintering is subjected to a drying process, and the semiconductor element 20 is placed on the metal material for sintering. Thereafter, the metal material for sintering is subjected to a heating process, so that the first bonding layer 29 (sintered metal) is formed. During the heating process, the metal material for sintering may be pressurized.

The first conductive member 30 is bonded to the first electrode 21 and the second lead 12 (pad portion 121) via the second bonding layer 38 and the third bonding layer 39 by a reflow process, for example. A method for forming the second bonding layer 38 and the third bonding layer 39 is not particularly limited, and one example is as follows. First, conductive paste materials are applied onto the first electrode 21 and onto the pad portion 121, respectively. Here, the conductive paste material has higher viscosity than the metal material for sintering, and spreads less than the metal material for sintering. Next, the first conductive member 30 is placed on the conductive paste material and heated in a reflow furnace. As a result, the second bonding layer 38 and the third bonding layer 39 are formed. After bonding the first conductive member 30, the second conductive member 40 and the third conductive member 50 are bonded.

The first bonding layer 29 is made of a sintered metal and exhibits high thermal conductivity. More specifically, the first bonding layer 29 has higher thermal conductivity than the second bonding layer 38 made of a conductive paste.

The sealing resin 60 includes the resin obverse surface 61, the resin reverse surface 62, the pair of first resin side surfaces 63, and the pair of second resin side surfaces 64. From one of the first resin side surface 63 facing the x1 side in the first direction x, the terminal portions 122 of the second lead 12, the terminal portion 132 of the third lead 13, and the terminal portion 142 of the fourth lead 14 project. From the other of the first resin side surface 63 facing the x2 side in the first direction x, the terminal portion 112 of the first lead 11 projects.

In the semiconductor device A40, the first bonding layer 29 is interposed between the base portion 111 of the first lead 11 and the second electrode 22 of the semiconductor element 20, and is bonded to the base portion 111 and the second electrode 22. The second bonding layer 38 is interposed between the first electrode 21 and the first portion 31 of the first conductive member 30, and is bonded to the first electrode 21 and the first portion 31. The first bonding layer 29 includes a sintered metal. Such a configuration enables the semiconductor device A40 to handle a large current through the first conductive member 30. In addition, the first bonding layer 29 interposed between the base portion 111 and the second electrode 22 includes a sintered metal, and hence exhibits high thermal conductivity. Accordingly, even when heat generation from the semiconductor element 20 increases with an increase in current capacity of the semiconductor device A40, heat generated from the semiconductor element 20 can be efficiently conducted to the base portion 111 (first lead 11) via the first bonding layer 29. Therefore, the semiconductor device A40 is advantageous for improving heat dissipation while achieving a high current capacity. In addition, the semiconductor device A40 may have a configuration in common with the semiconductor device A10, thereby achieving the same effect as the semiconductor device A10.

The semiconductor device according to present disclosure is not limited to the above-described embodiments. The specific configuration of each part of the semiconductor device according to present disclosure may be freely changed in design.

The present disclosure includes the configurations described in the following clauses.

### Clause 1.

A semiconductor device comprising:
a first lead including a base portion;
a semiconductor element mounted on one side in a thickness direction of the base portion and having a first electrode disposed on the one side in the thickness direction and a second electrode disposed on the other side in the thickness direction;
a second lead spaced apart from the base portion in a first direction orthogonal to the thickness direction;
a first conductive member including a first portion bonded to the first electrode and a second portion bonded to the second lead, the first conductive member being electrically connected to the first electrode and the second lead;
a first bonding layer interposed between the base portion and the second electrode, and bonded to the base portion and the second electrode; and
a second bonding layer interposed between the first electrode and the first portion, and bonded to the first electrode and the first portion,
wherein the first bonding layer includes a sintered metal.

### Clause 2.

The semiconductor device according to clause 1, wherein the second bonding layer includes a conductive paste.

### Clause 3.

The semiconductor device according to clause 2, wherein the second bonding layer includes solder.

### Clause 4.

The semiconductor device according to any one of clauses 1 to 3, further comprising a third bonding layer interposed between the second lead and the second portion, and bonded to the second lead and the second portion.

### Clause 5.

The semiconductor device according to clause 4, wherein the third bonding layer includes a conductive paste.

### Clause 6.

The semiconductor device according to clause 5, wherein the third bonding layer includes solder.

### Clause 7.

The semiconductor device according to any one of clauses 1 to 6, wherein the first bonding layer has a dimension along the thickness direction smaller than a dimension of the second bonding layer along the thickness direction.

### Clause 8.

The semiconductor device according to any one of clauses 1 to 7, wherein the second lead is elongated in the first direction.

### Clause 9.

The semiconductor device according to any one of clauses 1 to 8, wherein the first conductive member is a plate-shaped metal member.

### Clause 10.

The semiconductor device according to clause 9, wherein the first conductive member contains copper.

### Clause 11.

The semiconductor device according to any one of clauses 1 to 10, further comprising: a third lead spaced apart from the base portion and the second lead; and a second conductive member,

wherein the second conductive member is electrically connected to the first electrode and the third lead.

### Clause 12.

The semiconductor device according to clause 11, wherein the third lead is spaced apart from the second lead in a second direction orthogonal to the thickness direction and the first direction.

### Clause 13.

The semiconductor device according to clause 11 or 12, wherein the second conductive member is conductively bonded to the first portion and the third lead.

### Clause 14.

The semiconductor device according to clause 13, wherein the second conductive member is a plate-shaped metal member.

### Clause 15.

The semiconductor device according to clause 13, wherein the second conductive member is a bonding wire.

### Clause 16.

The semiconductor device according to any one of clauses 11 to 15, further comprising: a fourth lead spaced apart from the base portion in the first direction; and a third conductive member,

wherein the semiconductor element has a third electrode disposed on the one side in the thickness direction,
the fourth lead is spaced apart from the third lead in a second direction orthogonal to the thickness direction and the first direction, and
the third conductive member is conductively bonded to the third electrode and the fourth lead.

### Clause 17.

The semiconductor device according to clause 16, wherein the semiconductor element is a switching element having a drain electrode, a source electrode, and a gate electrode, and

the first electrode is the source electrode, the second electrode is the drain electrode, and the third electrode is the gate electrode.

### Clause 18.

A vehicle comprising a power converter including the semiconductor device according to clause 17.

### REFERENCE NUMERALS

A10, A20, A30, A40: Semiconductor Device; B1: Vehicle; 11: First Lead; 111: Base Portion; 111A: First Obverse Surface; 111B: First Reverse Surface; 111C: Through Hole; 112: Terminal Portion; 12: Second Lead; 121: Pad Portion; 122: Terminal Portion; 13: Third Lead; 131: Pad Portion; 132: Terminal Portion; 14: Fourth Lead; 141: Pad Portion; 142: Terminal Portion; 20: Semiconductor Element; 21: First Electrode (Source Electrode); 22: Second Electrode (Drain Electrode); 23: Third Electrode (Gate Electrode); 25: Semiconductor Layer; 29: First Bonding Layer; 30: First Conductive Member; 31: First Portion; 32: Second Portion; 33: First Intermediate Portion; 38: Second Bonding Layer; 39: Third Bonding Layer; 40: Second Conductive Member; 41: Third Portion; 42: Fourth Portion; 43: Second Intermediate Portion; 49: Bonding Layer; 50: Third Conductive Member; 60: Sealing Resin; 61: Resin Obverse Surface; 62: Resin Reverse Surface; 63: First Resin Side Surface; 64: Second Resin Side Surface; 65: Opening; 66: Mounting Hole; 67: Recess; 80: Charging Facility; 81: AC-DC Converter (Power Converter); 82: Power Reception Device; 83: Storage Battery; 84: Drive System; t1, t2: Dimension

1. A semiconductor device comprising:
a first lead including a base portion;
a semiconductor element mounted on one side in a thickness direction of the base portion and having a first electrode disposed on the one side in the thickness direction and a second electrode disposed on the other side in the thickness direction;
a second lead spaced apart from the base portion in a first direction orthogonal to the thickness direction;
a first conductive member including a first portion bonded to the first electrode and a second portion bonded to the second lead, the first conductive member being electrically connected to the first electrode and the second lead;
a first bonding layer interposed between the base portion and the second electrode, and bonded to the base portion and the second electrode; and
a second bonding layer interposed between the first electrode and the first portion, and bonded to the first electrode and the first portion,
wherein the first bonding layer includes a sintered metal.

2. The semiconductor device according to claim 1, wherein the second bonding layer includes a conductive paste.

3. The semiconductor device according to claim 2, wherein the second bonding layer includes solder.

4. The semiconductor device according to claim 1, further comprising a third bonding layer interposed between the second lead and the second portion, and bonded to the second lead and the second portion.

5. The semiconductor device according to claim 4, wherein the third bonding layer includes a conductive paste.

6. The semiconductor device according to claim 5, wherein the third bonding layer includes solder.

7. The semiconductor device according to claim 1, wherein the first bonding layer has a dimension along the thickness direction smaller than a dimension of the second bonding layer along the thickness direction.

8. The semiconductor device according to claim 1, wherein the second lead is elongated in the first direction.

9. The semiconductor device according to claim 1, wherein the first conductive member is a plate-shaped metal member.

10. The semiconductor device according to claim 9, wherein the first conductive member contains copper.

11. The semiconductor device according to claim 1, further comprising: a third lead spaced apart from the base portion and the second lead; and a second conductive member,
wherein the second conductive member is electrically connected to the first electrode and the third lead.

12. The semiconductor device according to claim 11, wherein the third lead is spaced apart from the second lead in a second direction orthogonal to the thickness direction and the first direction.

13. The semiconductor device according to claim 11, wherein the second conductive member is conductively bonded to the first portion and the third lead.

14. The semiconductor device according to claim 13, wherein the second conductive member is a plate-shaped metal member.

15. The semiconductor device according to claim 13, wherein the second conductive member is a bonding wire.

16. The semiconductor device according to claim 11, further comprising: a fourth lead spaced apart from the base portion in the first direction; and a third conductive member,
wherein the semiconductor element has a third electrode disposed on the one side in the thickness direction,
the fourth lead is spaced apart from the third lead in a second direction orthogonal to the thickness direction and the first direction, and
the third conductive member is conductively bonded to the third electrode and the fourth lead.

17. The semiconductor device according to claim 16, wherein the semiconductor element is a switching element having a drain electrode, a source electrode, and a gate electrode, and
the first electrode is the source electrode, the second electrode is the drain electrode, and the third electrode is the gate electrode.

18. A vehicle comprising a power converter including the semiconductor device according to claim 17.
